(19) United States
(12) Patent Application Publication
(10) Pub. No.: US 2006/0093029 A1
(43) Pub. Date: May 4, 2006

(54) Apparatus and method for grey encoding modulated data

(76) Inventors: Matthew E. Becker, Harvard, MA (US); William D. Kesling, Davis, CA (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 10/976,568

(22) Filed: Oct. 29, 2004

(51) Int. Cl. H03K 9/04

(52) U.S. Cl. 375/239

(57) ABSTRACT

A method and apparatus for grey encoding modulated data are described. In one embodiment, the method includes encoding of an input data stream to form an encoded data stream according to a symbol alphabet. In one embodiment, a modulated signal is produced from the encoded data stream. In one embodiment, the modulated signal includes a distinct symbol waveform to represent each symbol within the encoded data stream. In one embodiment, waveforms included in the modulated signal, which have adjacent transitions, represent symbols that differ by a single bit. In one embodiment, bit error rate is improved by encoding the phase positions in an edge position modulation system with grey encoding. Other embodiments are described and claimed.

### FIELD

One or more embodiments relate to modulation. More particularly, one or more of the embodiments relates to a method and apparatus for grey encoding modulated data.

### BACKGROUND

Various forms of modulation have long been used to encode data with greater efficiency so that more data can be transmitted during a particular time period over a transmission medium. Combinations of various modulation techniques, such as, pulse width modulation, amplitude modulation and rise time modulation have been employed to improve the encoding density of modulation schemes. See, for example, U.S. Pat. No. 6,697,420 issued to Simon, entitled “Symbol-Based Signaling for an Electromagnetically-Coupled Bus System,” issued Feb. 24, 2004. However, such schemes often require pre-emphasis and channel equalization, which increases the cost and complexity of the system. Moreover, in any event, it remains desirable to improve coding density to allow for even higher bit rates.

### BRIEF DESCRIPTION OF THE DRAWINGS

The various embodiments of the present embodiments described herein are illustrated by way of example, and not by way of limitation, in the figures of the accompanying drawings and in which:

FIG. 1A is a timing diagram illustrating conventional encoding of an edge position modulated signal.

FIG. 1B is a block diagram illustrating grey encoding of an edge position modulated signal, in accordance with one embodiment.

FIG. 2 is a block diagram illustrating a modulator for grey encoding an edge position modulated input data stream.

FIG. 3 is a circuit diagram for implementing the modulator of FIG. 2, in accordance with one embodiment.

FIG. 4 is a timing diagram illustrating a symbol modulated according phase modulation, pulse width modulation and amplitude modulation, in accordance with one embodiment.

FIG. 5 is an interface for grey encoding a multiple modulation signal, in accordance with one embodiment.

FIG. 6 is a timing diagram illustrating a symbol modulated according leading edge and trailing edge phase modulation, in accordance with one embodiment.

FIG. 7 is a block diagram illustrating a leading edge phase modulator and a trailing edge phase modulator, in accordance with one embodiment.

FIG. 8 is a circuit diagram for implementing edge-to-pulse generator (EPG) of FIG. 6, in accordance with one embodiment.

FIG. 9 is a computer system, including a chipset 810, having a transceiver for grey encoding a multiple modulation encoded data stream, in accordance with one embodiment.

### DETAILED DESCRIPTION

In the following description, numerous specific details such as logic implementations, sizes and names of signals and buses, types and interrelationships of system components, and logic partitioning/integration choices are set forth to provide a more thorough understanding. It will be appreciated, however, by one skilled in the art that the embodiments described herein may be practiced without such specific details. In other instances, control structures and gate level circuits have not been shown in detail to avoid obscuring the embodiments described herein. Those of ordinary skill in the art, with the included descriptions, will be able to implement appropriate logic circuits without undue experimentation.

In the following description, certain terminology is used to describe features of the embodiments described herein. For example, the term “logic” is representative of hardware and/or software configured to perform one or more functions. For instance, examples of “hardware” include, but are not limited or restricted to, an integrated circuit, a finite state machine or even combinatorial logic. The integrated circuit may take the form of a processor such as a microprocessor, application specific integrated circuit, a digital signal processor, a micro-controller, or the like.

The digital bandwidth (BW) of a communications channel may be represented as:
BW =FₛNₛ (1)

Here, Fₛ is the frequency at which symbols are transmitted on a channel and Nₛ is the number of bits transmitted per symbol per clock cycle (“symbol density”). Channel refers to a basic unit of communication, for example, a board trace for a single ended signaling or the two complementary traces for differential signaling. Modulation techniques have been employed in some digital systems to encode multiple bits in each transmitted symbol, thereby increasing Nₛ. As described herein, the term “digital symbol” refers to a timing sequence of symbol alphabet used to encode input data. In other words, a digital symbol represents plural bits of data encoded according to a symbol alphabet. As described herein, the term “symbol waveform” refers to a signal waveform version of each digital symbol within a symbol alphabet and may alternately be referred to as a “transmitted symbol.”

In the following discussion a “pulse” refers to a symbol waveform having both a leading (rising) edge and a trailing (falling) edge. For pulse-based signaling, information may be encoded, for example, in edge positions and signal amplitudes between edge pairs. The embodiments described herein are not limited to pulse-based signaling, however, other signal waveforms, such as edge-based signaling and various types of amplitude, phase or frequency-modulated periodic waveforms may be implemented as well.

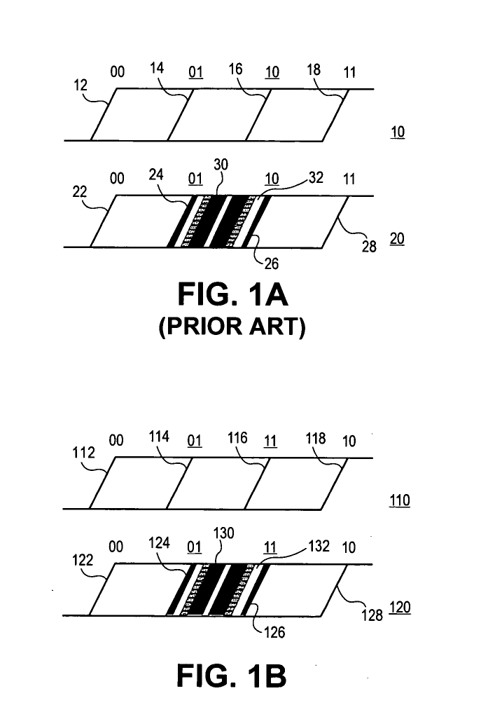

FIG. 1A illustrates timing diagrams to provide an example of four-phase (two bit) edge modulation signaling with conventional encoding. Representatively, the four phase positions (12, 14, 16 and 18) of symbol waveform 10 are encoded with a consecutive two bit sequence, referred to herein as “natural binary codes” (00, 01, 10, 11). However, symbol waveform 20 incurs noise (30 and 32) between second phase position 24 and third phase position 24; the noise can induce second phase position 24 to occur later in time. If the noise (30 and 32) is of sufficient magnitude, a receiver can mistake second phase position 24 as having occurred in third phase position 26. This would result in encoded bits “01” being mistaken as encoded bits “10” with conventional encoding, as shown in FIG. 1A, resulting in two incorrectly received bits. Conversely, the same noise event impacting first phase position 22 and second phase position 24 would be limited to one incorrectly received bit; namely, encoded bits “00” would be received or mistaken as encoded bits “01.”

In accordance with one embodiment, FIG. 1B is shown with the phase positions encoded according to grey encoding. In one embodiment, grey encoding is used to ensure that symbol waveforms having adjacent transitions differ by a single bit. In one embodiment, a symbol alphabet is formed using single distance digital symbols, such that transmitted symbol waveforms having adjacent transitions represent adjacent digital symbols. In one embodiment, each of two adjacent digital symbols represent bit sequences that differ by a single bit.

As shown in FIG. 1A, second phase position 24 and third phase position 26 are adjacent, however, differ by two bits. As shown in FIG. 1B, second phase position 114 encodes or represents bit pattern “01”, while third phase position 116 encodes bit pattern “11” such that adjacent phase position 124 and 126 are represented by adjacent bit sequences “01” and “11.” Accordingly, if symbol waveform 120 incurs noise between second phase position 124 and third phase position 126 and incorrectly decodes bit pattern “01” as bit pattern “11,” the resulting error is limited to one incorrectly received bit and therefore, results in half the bit error rate (BER), from what is shown in FIG. 1A.

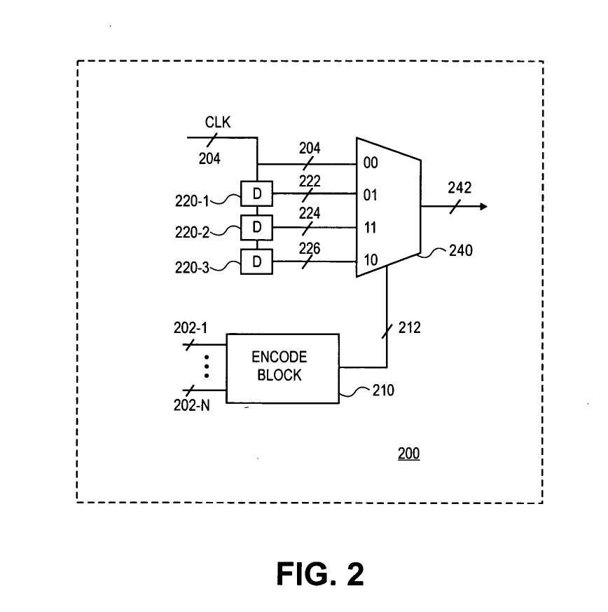

Accordingly, in one embodiment, a symbol alphabet for encoding phase positions in an edge position modulation system is described where the symbol alphabet is defined using single distance digital symbol edge positions such that transmitted symbol waveforms having adjacent edge positions represent adjacent digital symbols. In one embodiment, adjacent digital symbols represent bit sequences that differ by a single bit, for example, as shown in FIG. 1B. In one embodiment, modulator 200 for providing grey encoding to an edge position modulated data stream is illustrated with reference to FIG. 2.

Representatively, encode block 210 receives plural data bits 202 (202-1, . . . , 202-N), which may be encoded into time values 212. As described herein, these time values represent digital symbols of a symbol alphabet, which select a symbol waveform using logic gate, or multiplexor (MUX) 230. As illustrated, clock signal (CLK) 204 is provided to MUX 230. CLK signal 204 is also passed through delay blocks 220-1, 220-2 and 220-3, for example, to provide symbol waveforms 204, 222, 224 and 226 with phase positions, as shown in FIG. 1B.

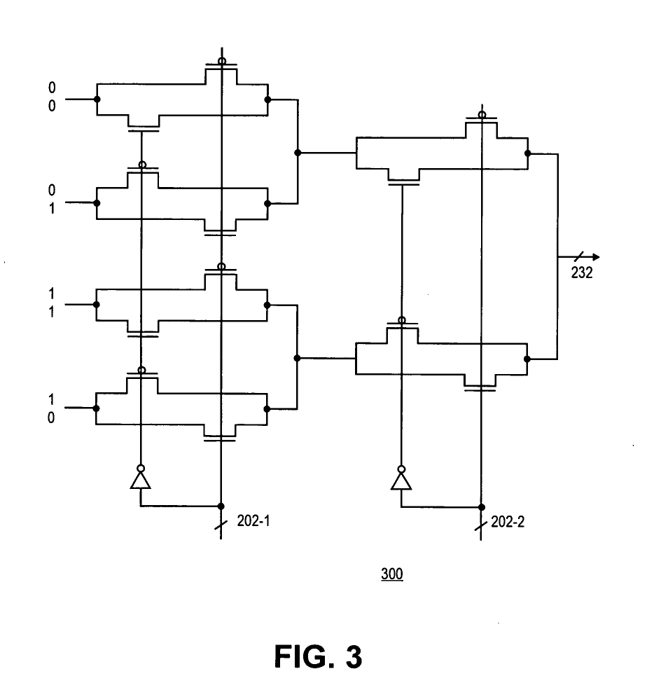

In accordance with one embodiment, symbol waveform 224 includes a third phase position, to encode bit pattern 11. Hence, if noise causes a phase position to be incorrectly decoded by a demodulator, a single bit error is incurred, as opposed to the multiple bit error incurred by conventional encoding of edge position modulated data, as shown in FIG. 1A. FIG. 3 illustrates a circuit diagram for implementing modulator 200 wherein the functionality of encode block 210 is incorporated into MUX 230, in accordance with one embodiment.

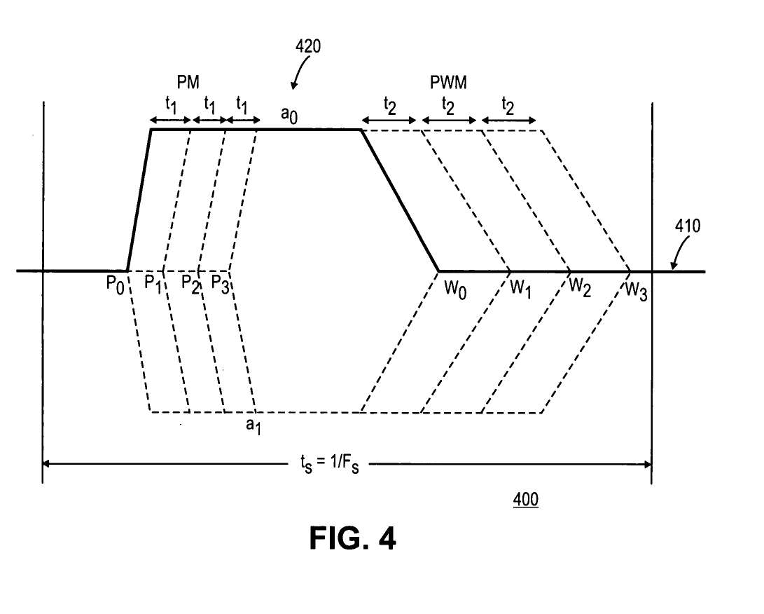

FIG. 4 is a timing diagram 400 that illustrates the interplay between Fₛ and Nₛ (See, Equation 1) and various modulation schemes that may be employed to encode multiple data bits into a digital symbol. Signal 410 includes symbol waveform 420 transmitted in a symbol period (Fₛ⁻¹). For purposes of illustration, phase, pulse width and amplitude modulation schemes are shown encoding five bits of data (Nₛ=5) in symbol waveform 420. In one embodiment, these modulations schemes, as well as others, alone or in combination, may be employed to increase the bandwidth for a particular system. The modulation scheme(s) may be selected by considering a bit interval (see below), noise sources, and circuit limitations applicable to each modulation scheme under consideration, and the symbol period available for a given frequency.

Referring again to FIG. 4, for signal 410, the value of first and second bits is indicated by where (P0, P1, P2 or P3) a leading edge of symbol waveform 420 occurs in the symbol period (phase modulation or PM). The value of the third and fourth bits are indicated by which of four possible widths (W0, W1, W2, W3) that the pulse has (pulse width modulation or PWM). The value of the fifth bit is indicated by whether the pulse amplitude is positive or negative (A0, A1) (amplitude modulation or AM). Solid lines indicate an actual state of symbol 420, and dashed lines indicate other available states for the described encoding schemes. In one embodiment, symbol waveforms having either a matching leading edge phase or a matching trailing edge width and an adjacent leading edge phase or an adjacent trailing edge width are identified as symbol waveforms having adjacent transitions.

As described herein, PM and PWM are examples of time-to-domain modulation schemes. Each time-to-domain modulation scheme encodes one or more bits in the time(s) at which one or more events, such as a rising edge or a rising edge followed by a falling edge, occur in the symbol period. That is, different bit states are represented by different events or differences between event times in the symbol period. A bit interval associated with each time-to-main modulation scheme represents a minimum amount of time necessary to reliably distinguish between the different bit states of the scheme. The modulation scheme selected for a particular system, the number of bits represented by a selected modulation scheme is determined, in part, by the bit intervals of candidate modulation schemes and time available to accommodate them, i.e., the symbol period.

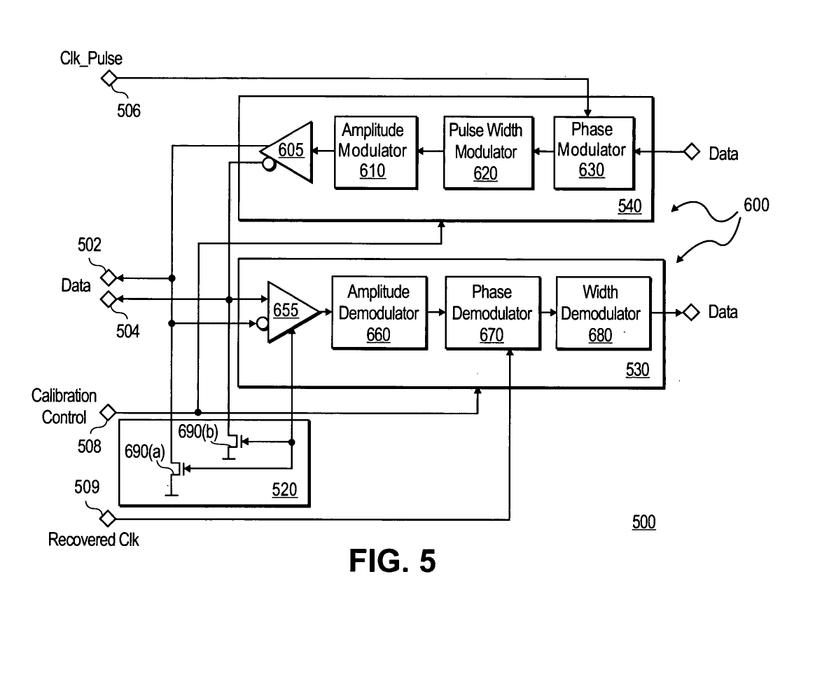

FIG. 5 is a block diagram of an interface 500 suitable for processing multi-bit symbols, such that symbol waveforms having adjacent transitions represent single distance digital symbols, where each two adjacent digital symbols represent bit sequences that differ by a single bit, in accordance with one embodiment. In one embodiment, interface 500 may be used to encode outbound bits from, for example, a memory interface to main memory. Representatively, interface 500 includes receiver 530 and a transmitter 540. Receiver 530 recovers the bits encoded in a transmitted symbol waveform on, for example, a bus. Embodiments of receiver 530 may include an amplifier to offset the attenuation of signal energy on transmission across, for example, electromagnetic couplers. Transmitter 540 encodes data bits provided by a controller into a symbol and drives a symbol waveform via a bus.

Calibration circuit 520 manages various parameters that may impact the performance of interface 500. In one embodiment, calibration circuit 520 may be used to adjust termination resistances, amplifier gains, or signal delays in interface 500, responsive to variations in process, temperature, voltage and the like. In one embodiment, interface 500 is suitable for handling waveforms in which data bits are encoded using phase, pulse width and amplitude modulation based on, for example, a signal, as shown in FIG. 4. In one embodiment, transmitter 540 and receiver 530 are collectively referred to as “transceiver” 600. In one embodiment, transceiver 600 supports differential signaling, as indicated by data pads 502, 504, and it receives calibration control signals from, e.g., calibration circuit 520 via control signals 508.

For the disclosed embodiment of transceiver 600, transmitter 540 includes a phase modulator 630, a pulse width modulator 620, an amplitude modulator 610 and an output buffer 605. Output buffer 605 provides inverted and non-inverted outputs to pad 502 and 504, respectively, to support differential signaling. A clock signal (CLK_PULSE) 506 is provided to phase modulator 610 to synchronize transceiver 600 with the system clock. The disclosed configuration of modulators 610, 620 and 630 is provided only for purposes of illustration. The corresponding modulation schemes may be applied in a different order or two or more schemes may be applied in parallel.

The disclosed embodiment of receiver 530 includes an amplifier 650, an amplitude demodulator 660, a phase demodulator 670 and a pulse width demodulator 680. The order of demodulators 660, 670 and 680 is provided for illustration and is not required to illustrate the described embodiments. Representatively, phase demodulator 670 detects phase positions in received symbol waveforms using received clock (clk) 509. For example, various demodulators may operate on a signal in parallel or in an order different from that indicated.

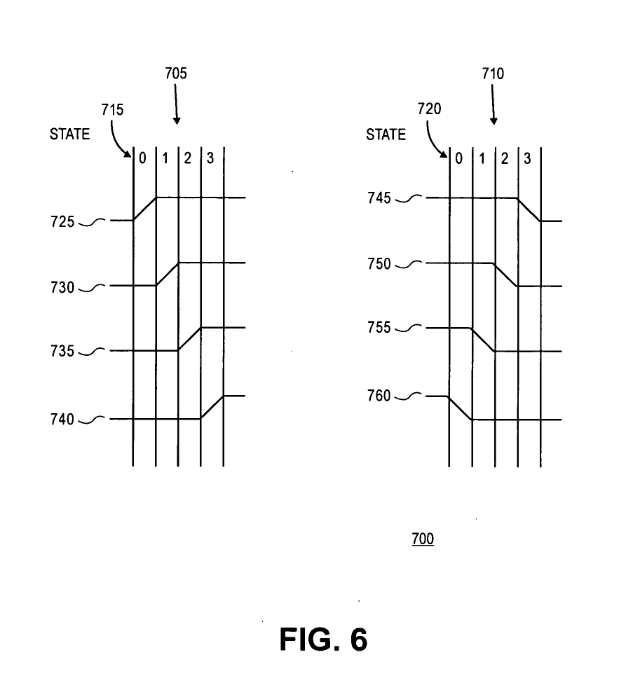

FIG. 6 illustrates signal modulation according to an embodiment that includes the use of leading edge modulation in combination with trailing edge modulation over a plurality of phase positions, in accordance with one embodiment. Representatively, symbols are illustrated for leading edge 705 and trailing edge 710. There are four possible phase positions for the leading edge 715 and the trailing edge 720. The illustrated lead edge symbols conclude at a first amplitude and the trailing edge symbols commence at the first amplitude. Any of the leading edge symbols (725, 730, 735 and 740), thus may be matched to any of the illustrate trailing edge symbols signals (745, 750, 755 and 760). The number of modulation states shown in FIG. 6 is thus 16 (4×4=16).

In one embodiment, symbol waveforms, such as leading edge symbol waveforms 705 and trailing edge symbol waveforms 710 are identified as symbol waveforms having adjacent transitions when the waveforms have a matching edge position at either a leading edge or a trailing edge and an adjacent edge position at a leading edge or trailing edge. For example, a symbol waveform composed of leading edge waveform 725 and trailing edge waveform 745 is adjacent to a symbol waveform composed of leading edge symbol waveform 730 and trailing edge symbol waveform 745. Likewise, the symbol waveform composed of leading edge symbol waveform 725 and trailing edge symbol waveform 750 is adjacent to the symbol waveform composed of leading edge symbol waveform 725 and trailing edge symbol waveform 745. Conversely, a symbol waveform composed of leading edge symbol waveform 730 and trailing edge symbol waveform 750 is not adjacent to a symbol waveform composed of leading edge symbol waveform 725 and trailing edge symbol waveform 745.

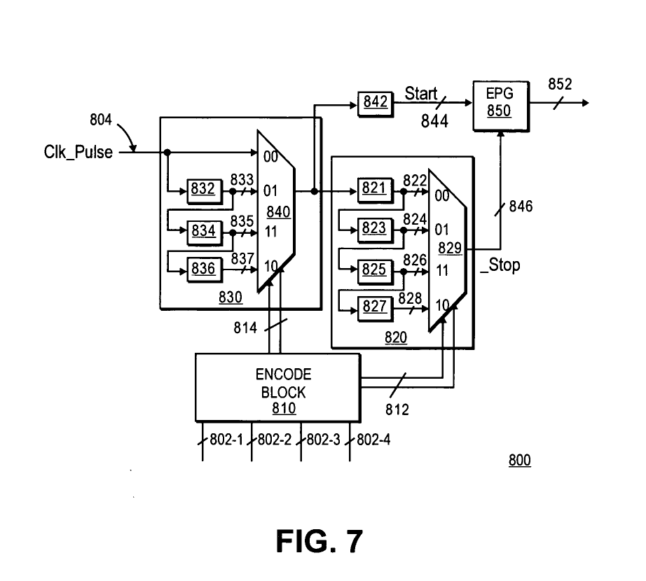

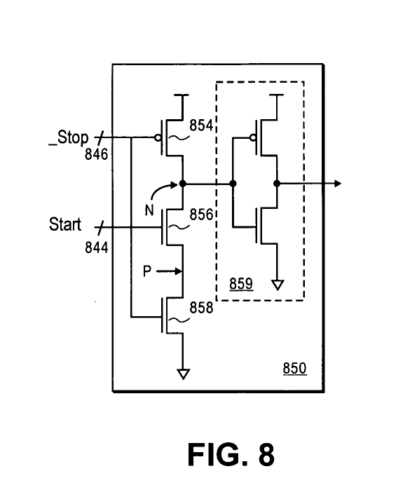

FIG. 7 illustrates a transceiver 800 suitable for handling waveforms in which data bits are encoded using leading edge and trailing edge phase modulation wherein transmitted symbol waveforms having adjacent phase positions represent single distance adjacent digital symbols, such that each two adjacent digital symbols represent bit sequences that differ by a single bit, in accordance with one embodiment. In one embodiment, transmitter 800 may be used to modulate an input data stream 802 (802-1, 802-2, 802-3 and 802-4) encoded according to a plural bit single distance symbol alphabet to output symbol waveform 852.

Representatively, transmitter 800 includes leading edge phase modulator 830 and trailing edge phase modulator 820. Representatively, encode block 810 may convert input data stream 802 into time position values (812 and 814). These time position values 814 may be used to select a leading edge, for symbol waveform 852. Likewise, the time values 812 may be used to select a phase position for a trailing edge of symbol waveform 852. Representatively, transmitter 800 modulates a clock signal (CLK_PULSE) to encode four outbound bits per symbol. Two bits are encoded in the symbol's leading edge phase and two bits are encoded in the symbol's trailing edge phase. In the embodiment illustrated, phase modulator 830 includes multiplexor (MUX) 840 and delay modules 832, 834 and 836. MUX 840 receives a delayed version of signal 804 as symbol waveforms.

In one embodiment, the control input of MUX 840 transmits one of waveforms 804, 833, 835 or 837 responsive to the value of phase bit 814. In general, a phase modulator 830 that encodes p-phase bits may select one of 2P versions of CLK_PULSE 804 subject to different delays. For the disclosed embodiment, the output of phase modulator 830 indicates the leading edge of symbol waveform 852 and serves as a timing reference for generation of the trailing edge by phase modulator 820. A delay-matching block (DMB) 842 is provided to offset circuit delays in phase modulator 820 (such as the delay of MUX 829), which might detrimentally impact the width of a symbol waveform 852. The output of DMB 842 is a start signal (START), which is provided to edge-to-pulse generator (EPG) 850.

Pulse modulator 820 includes DMs 821, 823, 825, 827 and MUX 829 to generate a second edge that is delayed relative to the first edge by an amount indicated by the phase bits 812. The delayed second edge forms a stop signal (_STOP) 846 that is input to EPG 850. For the disclosed embodiment of transmitter 800, two bits 812 applied to the control input of MUX 829 select one of four different delays for the second edge, which is provided at the output of MUX 829. Inputs 00, 01, 11 and 10 of MUX 829 sample the input signal, i.e., the first edge, following its passage through DMs 821, 823, 825 and 827, respectively. If the phase bits 812 indicate input 11, for example, the trailing edge output by MUX 829 is delayed by DM 821+DM 823+DM 825 relative to the leading edge.

In one embodiment, EPG 850 uses START 846 and _STOP 846 signals to generate symbol waveform 852 (pulse) having a leading edge and a trailing edge according to bits 812 and 814, respectively, provided to transmitter 800 for a given symbol period. On receipt of signal START 844, EPG 850 initiates a symbol pulse, which it terminates on receipt of signal 846 STOP to generate output symbol waveform 852. Accordingly, based on the values of leading edge phase bits 814 and trailing edge phase bits 812, output symbol waveform 852 is possible having any combination of leading edge waveforms 705 and trailing edge waveforms 710 of FIG. 6

FIG. 7 is a schematic diagram of one embodiment of EPG 850 that is suitable for use with the embodiments described herein. The disclosed embodiment of the EPG 850 includes transistors 854, 856 and 858 and inverter 859. The gate of N-type transistor 856 is driven by START signal 844. A positive-going edge on START signal 844 indicates the beginning of a symbol pulse. The gates of P and N-type transistors 854 and 858, respectively, are driven by _STOP signal 846. A negative-going edge on _STOP signal 846 indicates the end of a symbol pulse. When _STOP signal 846 is high, transistor 854 is off and transistor 858 is on. A positive-going edge on START signal 844 turns on transistor 856, pulling node N low and generating a leading edge for a symbol pulse 852 at the output of EPG 850 signal 846. A subsequent negative-going edge on _STOP, turns off transistor 858 and turns on transistor 854, pulling node N high and terminating the symbol pulse 852.

For a given symbol pulse, START may be deasserted (negative-going edge) before or after the corresponding _STOP is asserted. For example, the disclosed embodiment of transmitter 800 is timed with CLK_PULSE, and higher symbol densities may be obtained by employing narrow CLK_PULSEs. The widths of STARTS and _STOP are thus a function of the CLK_PULSE width, while the separation between START and _STOP is a function of the width bits. The different possible relative arrivals of the end of START and beginning of _STOP may adversely impact the modulation of symbol 852 by the phase bits 812. Specifically, transistor 858 may be on or off when a negative-going edge of _STOP terminates the symbol pulse. Node N may thus either be exposed to the parasitic capacitances at node P through transistor 854, or not. This variability may affect the delay of trailing symbol edge through EPG 850 in an unintended way.

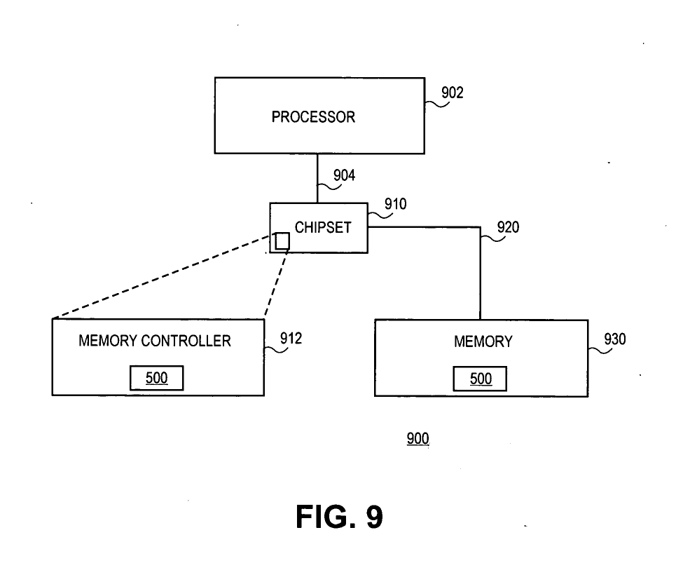

FIG. 9 is a block diagram illustrating a computer system 900 including transceiver 500 for grey encoding modulated data, in accordance with one embodiment. Computer system 900 comprises a processor system bus (front-side bus (FSB)) 904 for communicating information between a processor (CPU) 902 and a chipset 810, coupled together via FSB 104. As described herein, the term “chipset” is used in a manner well known to those of ordinary skill in the art to describe collectively, the various devices coupled to the CPU 902 to perform desired system functionality. Although the embodiment depicted illustrates memory controller 912 with transceiver 500 within chipset 810, chipset 8910 and memory controller 812 may be embodied or integrated within CPU 902.

The chipset 810 is also coupled to main memory 110, which also includes transceiver 500 for grey encoding modulated data. Memory controller 912 includes transceiver 500 to provide an interface with main memory 830 via memory bus 820. In one embodiment, BER is reduced by a factor or to when transceiver 500 modulate data according to edge position with symbol waveforms having neighboring edges representing bit sequences that differ by one bit. In one embodiment, main memory 830 is a volatile memory including, but not limited to, random access memory (RAM), static RAM (SRAM), double data rate (DDR), synchronous DRAM (SDRAM), rambus data RAM (RDRAM), or the like. In addition, hard disk drive devices HDD, as well as one or more input/output (I/O) devices may also couple to chipset 910. In one embodiment, FSB 904 is compatible with a Pentium® 4 front-side bus and is a pipelined data bus.

In the foregoing specification the features have been described with reference to specific embodiments thereof. It will, however, be evident that various modifications and changes can be made thereto without departing from the broader spirit and scope of embodiments as set forth in the appended claims. The specification and drawings are, accordingly, to be regarded in an illustrative rather than a restrictive sense.

### Alternate Embodiments

It will be appreciated that, for other embodiments, a different system configuration may be used. For example, while the system 900 includes a single CPU 902, for other embodiments, a multiprocessor system (where one or more processors may be similar in configuration and operation to the CPU 902 described above) may benefit from the grey encoding of modulated data of various embodiments. Further different type of system or different type of computer system such as, for example, a server, a workstation, a desktop computer system, a gaming system, an embedded computer system, a blade server, etc., may be used for other embodiments.

Having disclosed embodiments and the best mode, modifications and variations may be made to the disclosed embodiments while remaining within the scope of the embodiments as defined by the following claims.

What is claimed is:

1. A method comprising:
encoding an input data stream based on a plural bit symbol alphabet, the symbol alphabet defined such that transmitted symbol waveforms having an adjacent transition represent bit sequences that differ by a single bit; and
transmitting a modulated signal, the modulated signal including a symbol waveform to represent each digital symbol within the encoded data stream.

2. The method of claim 1, wherein the symbol alphabet is defined using single-distance digital symbols, such that each two adjacent digital symbols represent bit sequences that differ by one bit.

3. The method of claim 1, wherein symbol waveforms having adjacent pulse width represent digital symbols that differ by a single bit.

4. The method of claim 1, wherein symbol waveforms having adjacent leading edges represent digital symbols that differ by a single bit.

5. The method of claim 1, wherein symbol waveforms having adjacent trailing edges represent digital symbols that differ by a single bit.

6. The method of claim 1, wherein encoding further comprises encoding received binary data bits into time position values; and
assigning time position values according to the received data bits to form the encoded data stream.

7. The method of claim 1, wherein prior to encoding, the method further comprises:
generating a single distance symbol alphabet including a unique plural bit symbol to represent each of the plurality of symbol waveforms, wherein symbol waveforms having an adjacent phase position represent adjacent digital symbols, such that each two adjacent digital symbols represent bit sequences that differ by one bit.

8. The method of claim 7, wherein symbol waveforms having adjacent transition include symbol waveforms having one of a matching trailing edge and a matching leading edge in combination with one of an adjacent leading edge and an adjacent trailing edge.

9. The method of claim 1, where waveforms having adjacent leading transitions represent symbols that differ by a single bit.

10. The method of claim 1, wherein each plural bit symbol includes at least one redundancy bit.

11. A method comprising:
modulating input data encoded according to a plural bit symbol alphabet using a plurality of symbol waveforms, the symbol alphabet defined using single distance digital symbols, wherein symbol waveforms having an adjacent transition represent adjacent digital symbols, such that each two adjacent symbols represent bit sequences that differ by only one bit.

12. The method of claim 11, wherein symbol waveforms having adjacent transitions include symbol waveforms having one of a matching trailing edge and a matching leading edge in combination with one of an adjacent leading edge and an adjacent trailing edge.

13. The method of claim 11, wherein modulating further comprises:
receiving a digital symbol from an encoded input data stream;
selecting a waveform corresponding to the received digital symbol; and
transmitting the selected waveform during a symbol period, the selected waveform providing both leading edge and trailing edge modulation.

14. The method of claim 11, wherein the encoded input data is modulated over a plurality of time slots.

15. The method of claim 11, wherein symbol waveforms having adjacent leading transitions represent digital symbols that differ by a single bit.

16. The method of claim 14, wherein symbol waveforms having adjacent leading edges represent digital symbols that differ by a single bit.

17. The method of claim 14, wherein symbol waveforms having adjacent trailing edges represent digital symbols that differ by a single bit.

18. The method of claim 11, wherein each digital symbol within the symbol alphabet includes at least one redundancy bit.

19. The method of claim 11, wherein modulating further comprises:
delaying a clock signal to form the plurality of symbol waveforms; and
transmitting a pulse according to a time position assigned to at least two input data bits.

20. The method of claim 11, wherein modulating further comprises:
transmitting a pulse during a symbol period, the pulse providing both leading edge and trailing edge phase modulation.

21. An apparatus, comprising:
a controller having an interface to modulate an input data stream encoded according to plural bit symbol alphabet using a plurality of symbol waveforms, the symbol alphabet defined such that symbol waveforms having an adjacent transition represent bit sequences that differ by only one bit.

22. The apparatus of claim 21, wherein the interface comprises an edge position modulation interface to produce a modulated signal, the modulated signal being modulated over a plurality of phase positions.

23. The apparatus of claim 22, wherein the edge position modulation interface further comprises:
a modulator to delay a clock signal to form the plurality of symbol waveforms and to transmit a pulse according to a time position assigned to at least two input data bits.

24. The apparatus of claim 23, wherein the modulator further comprises:
an edge-to-pulse generator to transmit a pulse during a symbol period, the pulse providing both leading edge and trailing edge phase modulation.

25. The apparatus of claim 22, wherein the edge position modulation interface further comprises:
an encoder to encode received binary data bits into time position values and to assign time position values according to the received data bits to form the encoded data stream.

26. A system comprising:
a processor;
a chipset coupled to the processor, the chipset including a memory interface having a transceiver including at least one modulator to modulate an input data stream encoded according to plural bit symbol alphabet using a plurality of symbol waveforms, the symbol alphabet defined using single distance digital symbols, wherein symbol waveforms having adjacent transitions represent adjacent digital symbols such that each two adjacent digital symbols represent bit sequences that differ by one bit; and
a memory coupled to the chipset and having a transceiver including at least one demodulator to receive a symbol encoded by the modulator and to decode the symbol according to at least one time position value.

27. The system of claim 26, wherein the chipset comprises a memory controller.

28. The system of claim 26, wherein the memory comprises a dynamic random access memory.

29. The system of claim 26, wherein the interface comprises an edge position modulation interface.
